(19) United States
(12) Patent Application Publication
(10) Pub. No.: US 2011/0304978 A1
(43) Pub. Date: Dec. 15, 2011

(54) ENCLOSURE OF ELECTRONIC DEVICE

(75) Inventors: HONG-ZHI SUN, Shenzhen City (CN); CHEN CHEN, Shenzhen City (CN); YANG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/939,161

(22) Filed: Nov. 3, 2010

(30) Foreign Application Priority Data
Jun. 10, 2010 (CN) 201010197117.5

(51) Int. Cl. G06F 1/20; H05K 7/20

(52) U.S. Cl. 361/679.47; 174/548

(57) ABSTRACT

An enclosure of an electronic device includes a bottom wall and a sidewall. A motherboard is mounted on the bottom wall. The motherboard includes a heat generation apparatus and a heat sink attached thereon. The heat sink is in contact with the heat generation apparatus, and is configured to transmit heat from the heat generation apparatus to the heat sink. The sidewall defines a number of vents, which are in alignment with the heat sink. A fan is mounted between the sidewall and the heat sink with an air inlet side of the fan directed towards the heat sink and an air outlet side of the fan directed towards the plurality of vents.

### BACKGROUND

1. Technical Field

The present disclosure relates to enclosures of electronic devices, more particularly to an enclosure of an electronic device capable of dissipating heat quickly.

2. Description of Related Art

Various electrical instruments nowadays, and especially the desktop computers, are crowded with different electrical components and peripheral devices, such as central processing units (CPUs), interface cards, data storage devices, and power supplies. These electrical components and peripheral devices generate heat during operation. The inner temperature of the desktop computer enclosure can become very high. Therefore, one or more heat dissipation devices, such as fans, are installed inside the computer chassis to remove the heat generated by the electrical components and peripheral devices, to ensure that the inside of the computer chassis maintains a moderate operating temperature. However, because the electrical instruments are crowded together in a relatively small space, even with the fans, airflow may be severely restricted and therefore effectiveness of the fans to dissipate heat is restricted as well.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric and exploded view of an enclosure of an electronic device in accordance with an embodiment.

FIG. 2 is a partially assembled view of the enclosure of FIG. 1.

FIG. 3 is an assembled view of the enclosure of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

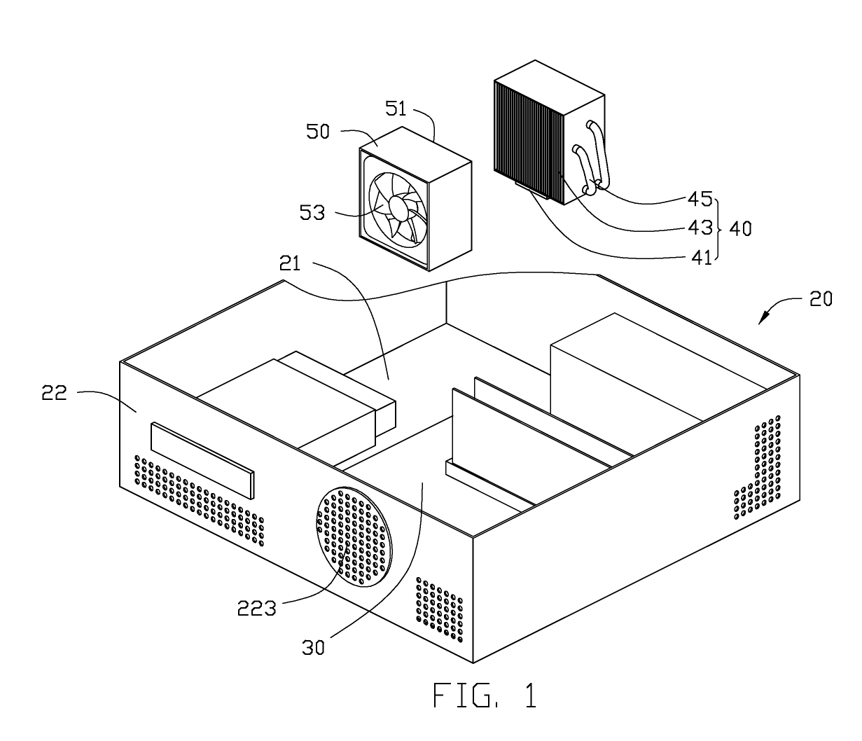

Referring to FIG. 1, an enclosure of an electronic device in accordance with an embodiment includes a chassis 20, a motherboard 30, a heat sink 40, and a fan 50.

The chassis 20 includes a bottom wall 21 and a sidewall 22 perpendicularly connected to an edge of the bottom wall 21. The motherboard 30 is mounted on the bottom wall 21. A heat generation apparatus, such as a CPU (not shown), is attached on the motherboard 30. The sidewall 22 defines a plurality of vents 223 in alignment with the heat generation apparatus.

The heat sink 40 includes a base 41, a number of parallel fins 43, and a number of heat pipes 45. The fins 43 are mounted on the base 41. Every two adjacent fins 43 define an air channel therebetween. The heat pipes 45 connect to the fins 43 to be in contact with the fins 43 and the base 41 simultaneously.

The fan 50 includes an air inlet side 51 and an air outlet side 53 opposite to the air inlet side 51.

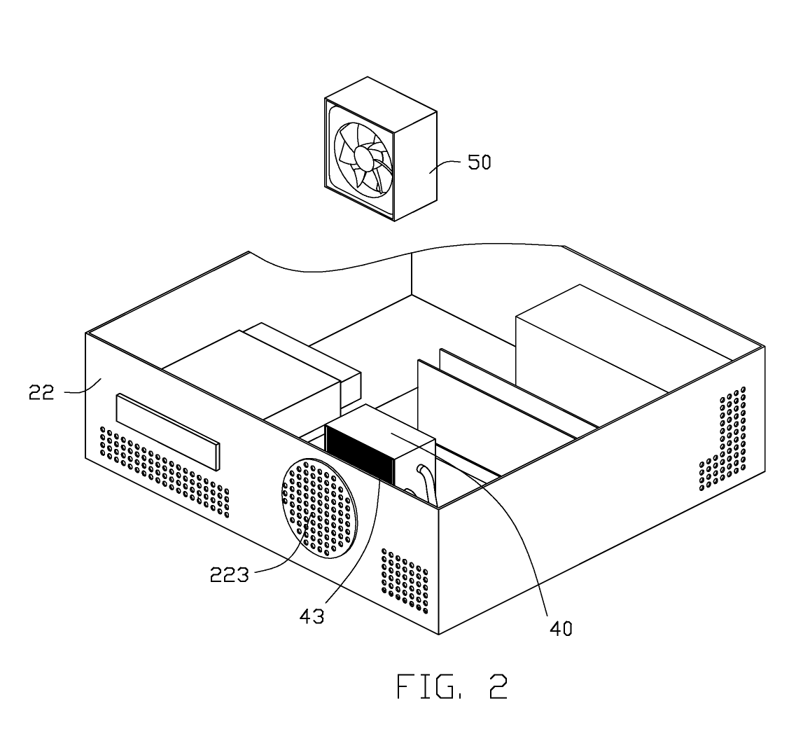

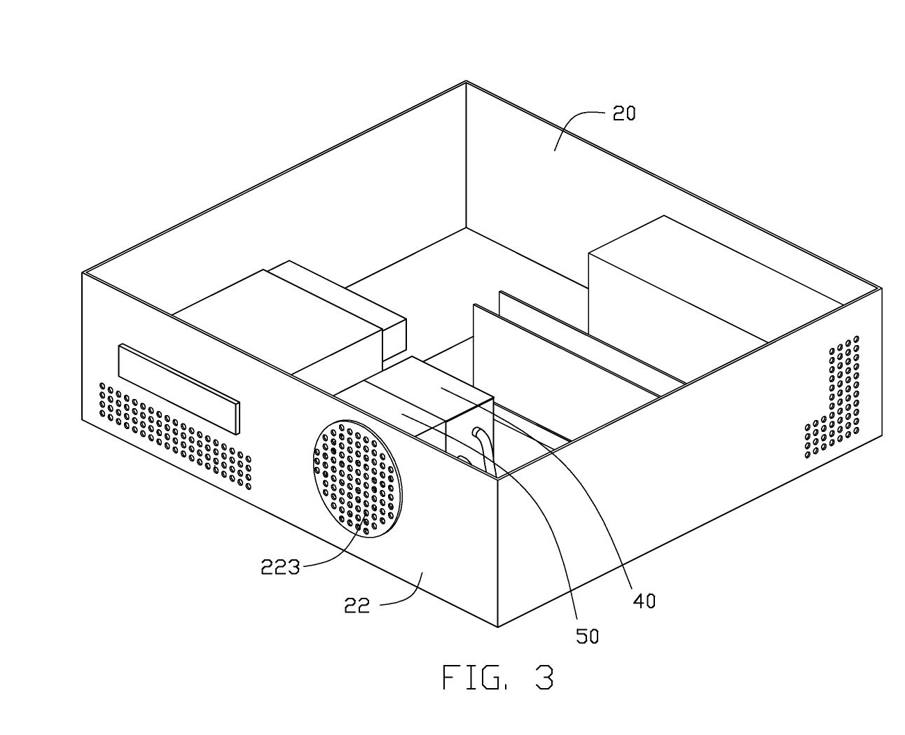

Referring to FIGS. 1 to 3, the base 41 of the heat sink 40 is in contact with the heat generation apparatus. Thus, heat generated by the heat generation apparatus is transmitted to the base 41, the heat pipes 45, and the fins 43 of the heat sink 40. A distance between the fins 43 and the sidewall 22 is equal to a width of the fan 50. The fan 50 is then mounted between fins 43 and the sidewall 22 with the air inlet side 51 facing the fins 43 and the air outlet side 53 facing the vents 223. The air inlet side 51 contacts the fins 43, and the air outlet side 53 contacts the sidewall 22. Therefore, when the fan 50 rotates, air in the air channels of the fins 43 is driven to flow out of the chassis 20 via the vents 223. Heat is therefore dissipated.

In the above enclosure, because there are no barriers among the heat sink 40, the fan 50, and the vents 223, airflow is less restricted and heat is dissipated quickly and efficiently.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. An enclosure of an electronic device, comprising:
a bottom wall, and a motherboard mounted on the bottom wall, the motherboard comprising a heat generation apparatus and a heat sink attached thereon, the heat sink is in contact with the heat generation apparatus and is configured to transmit heat from the heat generation apparatus to the heat sink; and
a sidewall defining a plurality of vents, the plurality of vents are in alignment with the heat sink, a fan mounted between the sidewall and the heat sink with an air inlet side of the fan directed towards the heat sink and an air outlet side of the fan directed towards the plurality of vents.

2. The enclosure of claim 1, wherein the heat sink comprises a base and a plurality of parallel fins mounted on the base, the plurality of parallel fins are perpendicular to the sidewall, and every two adjacent fins defines an air channel therebetween.

3. The enclosure of claim 2, wherein a distance between the plurality of parallel fins and the sidewall is equal to a width of the fan.

4. The enclosure of claim 2, wherein the heat sink comprises a plurality of heat pipes, the plurality of heat pipes are in contact with the plurality of parallel fins and the base simultaneously.

5. The enclosure of claim 2, wherein the fan is configured to drive air from the air channel to the plurality of vents and out of the enclosure.

6. The enclosure of claim 2, wherein the air inlet side is in contact with the plurality of parallel fins, and the air outlet side is in contact with the sidewall.

7. An enclosure of an electronic device, comprising:
a bottom wall, a heat generation apparatus and a heat sink attached on the bottom wall, the heat sink comprising a plurality of parallel fins, every two adjacent fins defining an air channel therebetween, the heat sink is in contact with the heat generation apparatus and is configured to transmit heat from the heat generation apparatus to the plurality of parallel fins;
a sidewall connected with the bottom wall and positioned perpendicular to the plurality of parallel fins, the sidewall defining a plurality of vents, the plurality of vents are in alignment with the plurality of parallel fins; and
a fan sandwiched between the sidewall and the plurality of parallel fins with an air inlet side of the fan directed towards the plurality of parallel fins and an air outlet side of the fan directed towards the plurality of vents, the fan is configured to drive air from the air channel to the plurality of vents.

8. The enclosure of claim 7, wherein the heat sink comprises a base, the plurality of parallel fins are mounted on the base, and the base is in contact with the heat generation apparatus.

9. The enclosure of claim 8, wherein the heat sink comprises a plurality of heat pipes, the plurality of heat pipes are in contact with the plurality of parallel fins and the base simultaneously.

10. The enclosure of claim 7, wherein a distance between the plurality of parallel fins and the sidewall is equal to a width of the fan.

11. The enclosure of claim 7, wherein the air inlet side is in contact with the plurality of parallel fins, and the air outlet side is in contact with the sidewall.
